(19) United States
(12) Patent Application Publication
(10) Pub. No.: US 2017/0129032 A1
(43) Pub. Date: May 11, 2017

(54) BALL BOX AND SOLDER BALL ATTACHMENT APPARATUS HAVING THE SAME

(71) Applicant: Samsung Electronics Co., Ltd., Suwon-si (KR)

(72) Inventors: Young-bok KIM, Asan-si (KR); Hee-chul KANG, Cheonan-si (KR); Young-jin JU, Cheonan-si (KR); Jun-ho SONG, Asan-si (KR); Seung-jin CHEON, Asan-si (KR); Young-rae KIM, Asan-si (KR); Hyeong-gyu KIM, Asan-si (KR); Sang-kyu YEON, Hongseong-gun (KR)

(73) Assignee: Samsung Electronics Co., Ltd., Suwon-si (KR)

(21) Appl. No.: 15/220,900

(22) Filed: Jul. 27, 2016

(30) Foreign Application Priority Data
Nov. 9, 2015 (KR) 10-2015-0156746

(51) Int. Cl. B23K 3/06; H01L 23/00

(52) U.S. Cl. CPC B23K 3/0623; H01L 24/75; H01L 2224/75601; H01L 2224/75745

(57) ABSTRACT

A solder ball attachment apparatus including an open ball box configured to accommodate a plurality of solder balls, the open ball box including, a pocket portion at a bottom thereof, the pocket portion configured to accommodate the solder balls, and an inclined portion extending from the pocket portion toward an outer surface of the open ball box, a solder ball attachment tool configured to apply suction pressure to a lower surface thereof, the lower surface configured to face the open ball box, the lower surface configured to adsorb the solder balls accommodated in the ball box by moving between a first position and a second position, the first position being a standby position, the second position being a position for adsorbing the solder balls, and a vibration member connected to the open ball box may be provided.

### CROSS-REFERENCE TO RELATED APPLICATION

This application claims priority under 35 U.S.C. §119 to Korean Patent Application No. 10-2015-0156746, filed on Nov. 9, 2015, in the Korean Intellectual Property Office, the disclosure of which is incorporated herein in its entirety by reference.

### BACKGROUND

The inventive concepts relate to ball boxes used in a solder ball attachment process, and/or solder ball attachment apparatuses including the ball box.

In order to attach solder balls to a semiconductor substrate, a method of applying vibration to a ball box, which accommodates a large number of solder balls, has been used to bounce the solder balls to a desired (or alternatively, predetermined) height and a method of adsorbing the bounced solder balls by using a solder ball attachment tool, which is capable of applying suction pressure, has been used, However, there has been a problem in that the solder balls bounced by vibration in the ball box escape the ball box.

### SUMMARY

Some example embodiments of the inventive concepts provide ball boxes that mitigate or prevent solder balls from escaping to the outside.

According to an example embodiment of the inventive concepts, a solder ball attachment apparatus includes an open ball box configured to accommodate a plurality of solder balls, the open ball box including a pocket portion at a bottom thereof, the pocket portion configured to accommodate the solder balls and an inclined portion extending from the pocket portion toward an outer surface of the open ball box, a solder ball attachment tool configured to apply suction pressure to a lower surface thereof, the lower surface configured to face the open ball box, the lower surface configured to adsorb the solder balls accommodated in the ball box by moving between a first position and a second position, the first position being a standby position, the second position being a position for adsorbing the solder balls, and a vibration member connected to the open ball box.

In some example embodiments of the inventive concepts, the pocket portion may include a bottom surface having a first level, and a side surface extending from an edge of the bottom surface to a second level higher than the first level.

In some example embodiment of the inventive concepts, when the solder ball attachment tool is positioned at the second position, the solder ball attachment tool may be spaced apart from the bottom surface and the side surface of the pocket portion, and the lower surface may be located between the first level and the second level.

In some example embodiment of the inventive concepts, the solder ball attachment tool may include a first frame portion and a second frame portion, the first frame portion having a first width, and the second frame portion above the first frame portion and having a second width larger than the first width.

In some example embodiment of the inventive concepts, the pocket portion may have a width larger than the first width and smaller than the second width.

In some example embodiment of the inventive concepts, when the second frame portion is positioned at the second position spaced apart from a boundary between the pocket portion and the inclined portion, the apparatus may be configured to have a height difference between a bottom surface of the second frame portion and the boundary of at least approximately 2 mm or more.

In some example embodiment of the inventive concepts, the inclined portion may be connected to the pocket portion and surrounds the pocket portion,

In some example embodiment of the inventive concepts, the inclined portion may extend from a first point to a second point, the first point connected to the pocket portion, the second point spaced apart from the first point by a distance in a direction toward the outer surface of the open ball box, a height of the second point being higher than that of the first point.

In some example embodiment of the inventive concepts, the inclined portion may include a concave surface.

In some example embodiment of the inventive concepts, the pocket portion may constitute a rectangular parallelepiped space.

According to an example embodiment of the inventive concepts, a solder ball attachment ball box may include an open container body, which includes an opening on atop side thereof, a pocket portion configured to accommodate the solder balls and be aligned with the opening, and an inclined portion extending from the pocket portion toward an exterior side surface of the body

In some example embodiment of the inventive concepts, the pocket portion may be spaced apart from the outer surface of the open ball box by the inclined portion interposed therebetween.

In some example embodiment of the inventive concepts, the inclined portion may include an inclined surface and a concave surface, the inclined surface connected to the pocket portion, the concave surface connected to the inclined surface.

In some example embodiment of the inventive concepts, the pocket portion may include a bottom surface and aside surface, the side surface of the pocket portion extending from an edge of the bottom surface, and the bottom surface and the side surface may constitute a rectangular parallelepiped space.

In some example embodiment of the inventive concepts, a height level of the inclined portion may increase toward the outer surface of the body.

According to an example embodiment of the inventive concepts, a solder ball attachment apparatus includes a ball box including one open surface, the ball box having a body having an opening at one surface thereof, the opening aligned with the one open surface of the ball box, a pocket portion in the body, the pocket configured to accommodate the solder balls, and an inclined portion extending from the pocket portion toward a side surface of the body.

In some example embodiment of the inventive concepts, the inclined portion may include a concave surface.

In some example embodiment of the inventive concepts, the inclined portion may extend from a first point to a second point, the first point connected to the pocket portion, the second point spaced apart from the first point by a distance in a direction toward the exterior side surface of the open container body, a height of the second point being higher than that of the first point.

In some example embodiment of the inventive concepts, the apparatus may further include a solder ball attachment tool configured to apply suction pressure to a lower surface thereof, the solder ball attachment tool configured to ascend and descend, the solder ball attachment tool configured to face the body at the lower surface thereof and adsorb the solder balls accommodated in the body.

In some example embodiment of the inventive concepts, the apparatus of may further include a vibration member configured to vibrate the body.

### BRIEF DESCRIPTION OF THE DRAWINGS

Example embodiments of the inventive concepts will be more clearly understood from the following detailed description taken in conjunction with the accompanying drawings in which:

FIG. 1 is a perspective view of a ball box according to an example embodiment of the inventive concepts;

FIG. 2 is a cross-sectional view of the bal box take along line II-II′ in FIG. 1;

FIG. 3 is a cross-sectional view of the ball box take along line III-III′ in FIG. 1 and schematically illustrates a solder ball supplier provided on one side of the ball box;

FIG. 4 is a schematic diagram illustrating solder balls that move on a concave surface of FIG. 3;

FIG. 5 is a cross-sectional view of a solder ball attachment apparatus according to an example embodiment of the inventive concepts;

FIG. 6 is a schematic diagram illustrating a method of attaching solder balls onto a semiconductor substrate, according to an example embodiment of the inventive concepts;

FIG. 7 is a cross-sectional view illustrating some components of the solder ball attachment apparatus illustrated in FIG. 5; and

FIG. 8 is an enlarged view of a region VIII illustrated in FIG. 5.

### DETAILED DESCRIPTION OF EXAMPLE EMBODIMENTS

The inventive concepts will now be described more fully with reference to the accompanying drawings, in which some example embodiments of the inventive concepts are shown. The inventive concepts may, however, be embodied in many different forms, and should not be construed as being limited to the example embodiments set forth herein; rather, these example embodiments are provided so that this disclosure will be thorough and complete, and will fully convey the inventive concepts to one of ordinary skill in the art. In the drawings, the thicknesses of layers and regions are exaggerated for clarity. Like reference numerals denote like elements throughout the specification.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

In addition, relative terms such as “beneath,” “below,” “lower” or “bottom”, and “above,” “upper” or “top” may be used herein to describe one element's relationship to another as illustrated in the drawings. It will be understood that relative terms are intended to encompass different orientations of the device in addition to the orientation depicted in the drawings. For example, if a device in the drawings is inverted, elements described as being on the “lower” side of other elements would then be oriented on “upper” sides of the other elements. The example term “lower”, can therefore, encompasses both an orientation of “lower” and “upper”, depending of the particular orientation of the figure. Similarly, if a device in one of the drawings is inverted, elements described as “below” or “beneath” other elements would then be oriented “above” the other elements. The example terms “below” or “beneath” can, therefore, encompass both an orientation of above and below.

The terminology used herein is for the purpose of describing particular example embodiments only and is not intended to be limiting of the inventive concepts. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of example embodiments.

As such, variations from the shapes of the illustrations as a result of manufacturing techniques and/or tolerance, are to be expected. Thus, example embodiments of the inventive concepts should not be construed as limited to the particular shapes of regions illustrated herein but are to include deviations in shapes that result, for example, from manufacturing. Hereinafter, the inventive concepts may be constituted by one example embodiment or a combination of a plurality of example embodiments.

As used herein, the term “and/or” includes any and all combinations of one or more of the associated listed items. Expressions such as “at least one of,” when preceding a list of elements, modify the entire list of elements and do not modify the individual elements of the list. Thus, for example, both “at least one of A, B, or C” and “A, B, and/or C” means either A, B. C or any combination thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Although ball boxes and solder ball attachment apparatuses are described below to include sonic desired components, the inventive concepts are not limited thereto.

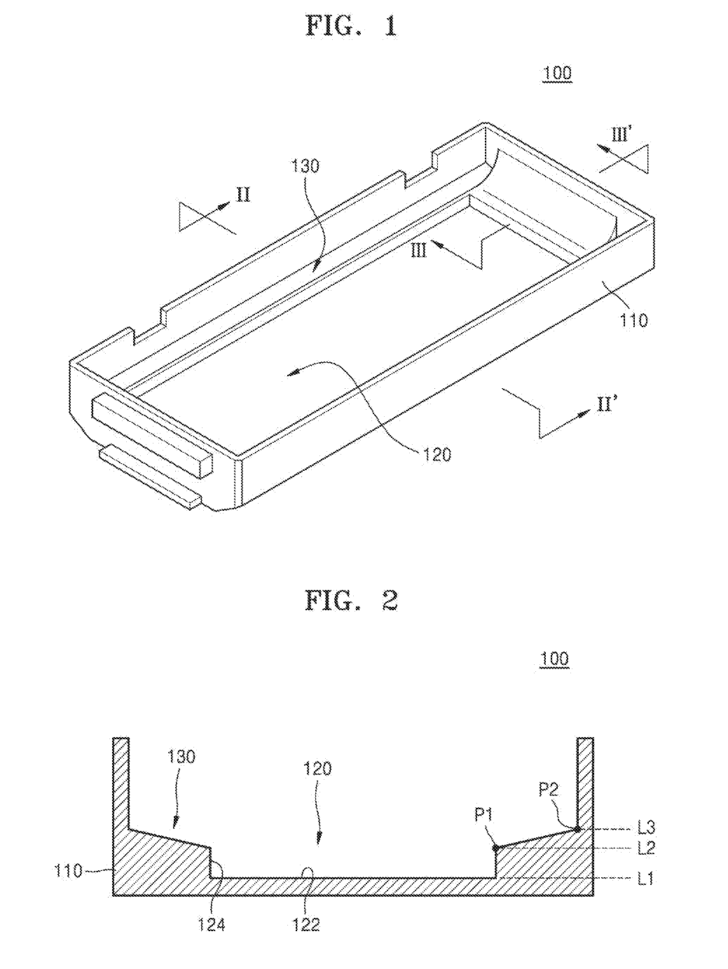

FIG. 1 is a perspective view of a ball box according to an example embodiment of the inventive concepts. FIG. 2 is a cross-sectional view of the ball box take along line II-II′ in FIG. 1.

Referring to FIGS. 1 and 2, a ball box 100 capable of accommodating a large number of solder balls is provided. The ball box 100 includes a body 110, a pocket portion 120, and an inclined portion 130.

The body 110 constitutes the overall appearance of the ball box 100, and may have one surface which is opened.

The pocket portion 120 may be defined inside the body and accommodate a large number of solder balls. The pocket portion 120 may have a depth which is sufficient to accommodate the large number of solder balls, and may provide a rectangular parallelepiped space of which one surface is opened.

The pocket portion 120 may include a bottom surface 122 and aside surface 124 which extends from an edge of the bottom surface 122. The bottom surface 122 is lower than its vicinities, and may be constituted by one plane. The large number of solder balls may be accumulated on the bottom surface 122. The side surface 124 may extend in a direction which is substantially perpendicular to the bottom surface 122. Assuming that the bottom surface 122 has a height of a first level L1 the side surface 124 may extend from the first L1 to a second level L2 which is higher than the first level L1.

The inclined portion 130 may be connected to the pocket portion 120 (e.g., the side surface 124), and may extend in a direction toward the outer surface (e.g., an exterior side surface) of the body 110 from the pocket portion 120. The inclined portion 130 may surround the edge of the pocket portion 120. Thus, the pocket portion 120 may be spaced apart from the side surface of the body 110 by the intervening inclined portion 130.

The inclined portion 130 may provide an inclined surface toward a lower portion from an upper portion of the ball box 100. That is, when a solder ball is positioned on the inclined portion 130 having a desired (or alternatively, predetermined) inclination, movements of the solder balls may be facilitated in a direction toward the pocket portion 120.

When a boundary between the inclined portion 130 and the pocket portion 120 (e.g., the side surface 124) is set to be a first point P1, the inclined portion 130 may extend from the first point P1 to a second point P2, which is spaced from the first point P1 in a direction toward the side surface of the body 110 at a desired (or alternatively, fixed) distance. At this time, a height level L3 of the second point P2 is higher than a height level L2 of the first point P1. For example, a difference between the height level L3 of the second point P2 and the height level L2 of the first point P1 may be approximately 0.2 mm.

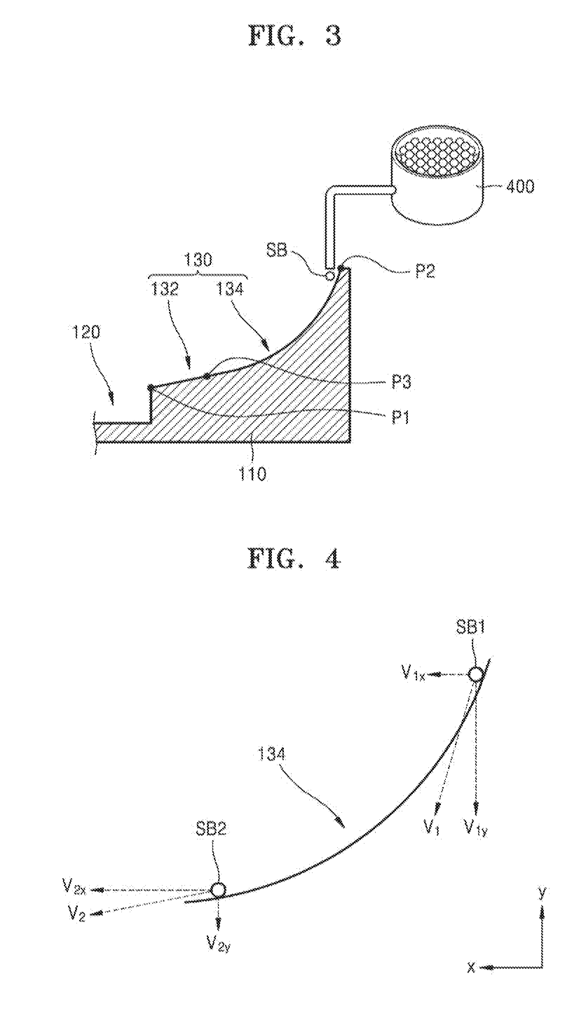

FIG. 3 is a cross-sectional view of the ball box take along line III-III′ in FIG. 1 and schematically illustrates a solder ball supplier provided on one side of the ball box. FIG. 4 is a schematic diagram illustrating solder balls that move on a concave surface of FIG. 3.

Referring to FIGS. 3 and 4, a solder ball supplier 400 may be provided adjacent to the ball box 100. The solder ball supplier 400 may store a large number of solder balls SB therein, and may supply the solder balls SB to one opened surface of the ball box 100 through a moving path (not shown) extending toward the ball box 100. The solder ball supplier 400 may be installed in the moving path and may include a supply valve, which is capable of controlling the number of solder balls SB to be supplied.

The solder balls SB supplied from the solder ball supplier 400 may be supplied to one point on the inclined portion 130 of the ball box 100, and the solder balls SB supplied to the ball box 100 may move toward the pocket portion 120 while rolling along the inclined portion 130.

In the example embodiments, the inclined portion 130 may include a concave surface 134 which the solder balls SB supplied from the solder ball supplier 400 fall on and collide with. The concave surface 134 may start from a third point P3, which is positioned between the first point P1 and the second point P2, and end at the second point P2. Here, when any two points of an arc, connecting the second point P2 and the third point P3, which is a section where the concave surface 134 extends, are connected to each other by a straight line, the straight line is defined as being present outside the body 110.

As illustrated in FIG. 3, the inclined portion 130 may include an inclined surface 132 having a fixed inclination and the concave surface 134 extending from the inclined surface 132. That is, the inclined portion 130 may include the inclined surface 132 extending with a fixed inclination from the first point P1 which is a boundary between the inclined portion 130 and the pocket portion 120 to the third point P3 which is spaced from the first point P1 by a fixed distance, and the concave surface 134 extending from the third point P3 to the second point P2. The first point P1 and the second point P2 are provided to be opposite to each other with respect to the second point P2.

In some example embodiment, the inclined portion 130 may be constituted by only the concave surface 134 extending from the first point P1 to the second point P2.

As illustrated in FIG. 4, the solder balls SB may move along the concave surface 134 from the second point P2 to the third point P3. The velocity of the solder ball SB at any point on the concave surface 134 may include a velocity component in a horizontal direction x and a velocity component in a vertical direction y. That is, a velocity v1 of a solder ball SB1 which is adjacent to the second point P2 is equal to a resultant velocity of a velocity component v1x in the horizontal direction x and a velocity component v1y in the vertical direction y, and a velocity v2 of a solder ball SB2 which is adjacent to the third point is equal to a resultant velocity of a velocity component v2x in the horizontal direction x and a velocity component v2y in the vertical direction y. Here, the horizontal direction x may be a direction which is substantially parallel to the bottom surface 122 in FIG, 2 of the pocket portion 120, and the vertical direction y may be a direction which is substantially perpendicular to the bottom surface 122.

Because the solder ball SB moves on the concave surface 134 along an inclination direction of the concave surface 134 (moving from the second point P2 toward the third point P3), the velocity in the vertical direction y may decrease from the second point P2 toward the third point P3, while the velocity in the horizontal direction x may increase from the second point P2 toward the third point P3. That is, a velocity v2x of the solder ball SB2 in the horizontal direction which is located at a point adjacent to a lower portion of the concave surface 134 is greater than a velocity v1x of the solder ball SB1 in the horizontal direction which is located at a point adjacent to an upper portion of the concave surface 134.

The inclined portion 130, on which the solder ball SB supplied from the solder ball supplier 400 falls, is configured to include the concave surface 134, and thus the velocity of the solder ball SB in the horizontal direction x may increase toward the pocket portion 120. As a result, the solder balls SB may be rapidly diffused inside the pocket portion 120 on the whole.

The degree of a decrease in the velocity of the solder ball SB due to collision increases as an angle between a falling direction (for example, the vertical direction y) of the solder ball SB and a collision surface at a falling point of the solder ball SB becomes closer to a right angle. Thus, if the solder ball SB falls on the concave surface 134 having an inclination close to a vertical direction, the velocity of the solder ball SB may not greatly decrease.

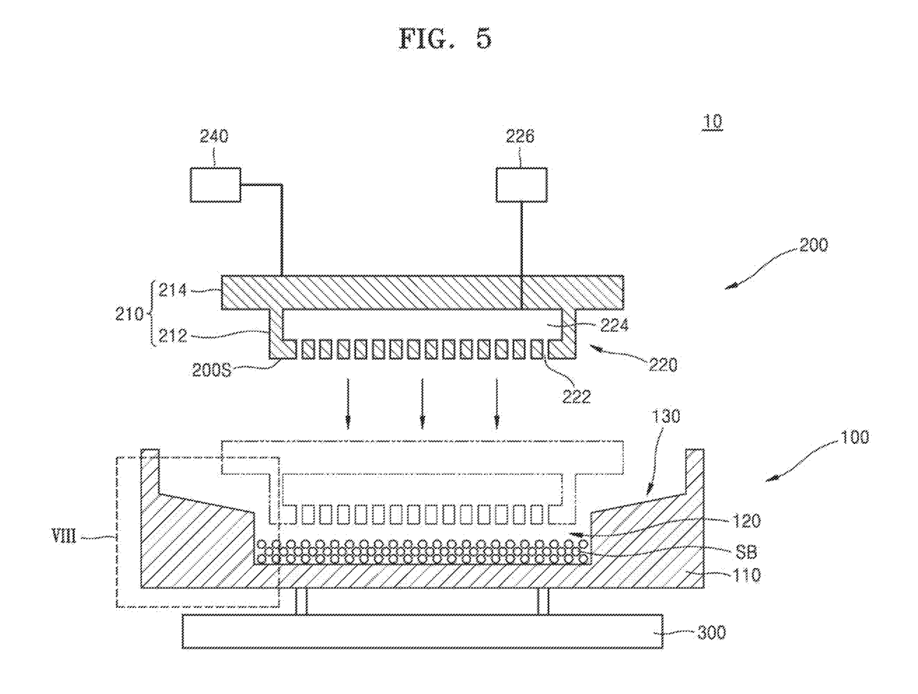

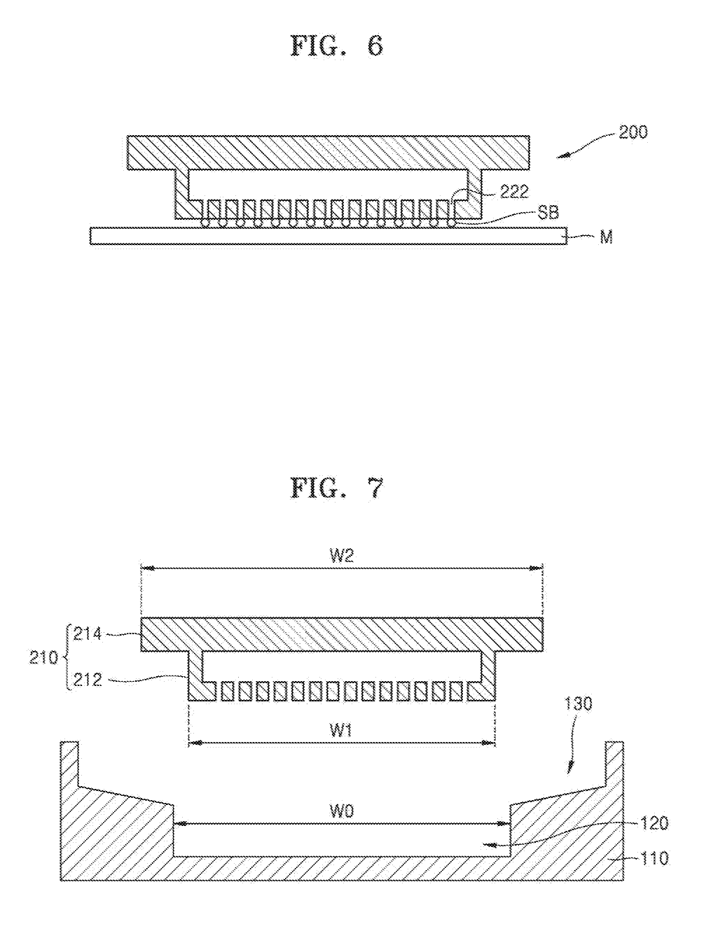

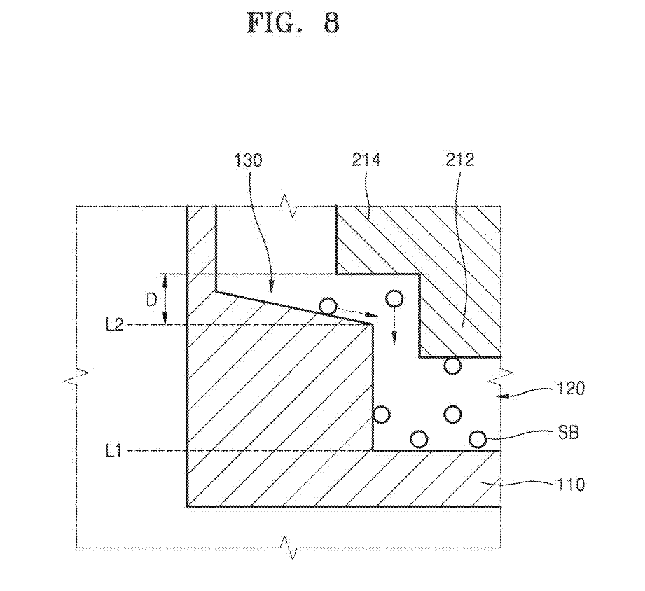

FIG. 5 is a cross-sectional view of a solder ball attachment apparatus 10 according to an example embodiment of the inventive concepts. FIG. 6 is a schematic diagram illustrating a method of attaching solder balls onto a semiconductor substrate, according to an example embodiment of the inventive concepts. FIG. 7 is a cross-sectional view illustrating some components of the solder ball attachment apparatus 10 illustrated in FIG. 5. FIG. 8 is an enlarged view of a region VIII illustrated in FIG. 5.

Referring to FIG. 5, the solder ball attachment apparatus 10 may include a solder ball attachment tool 200, a ball box 100, and a vibration member 300. The ball box 100 is substantially the same as the ball box 100 described above with reference to FIGS. 1 to 4, and a repeated description will be omitted or simplified.

The ball box 100 may be provided on as to face a lower surface 200S of the solder ball attachment tool 200, and may include a pocket portion 120 accommodating a large number of solder balls SB and an inclined portion 130, which is connected to the pocket portion 120 and extends toward the side surface of a body 110. A surface of the pocket portion 120 which faces the solder ball attachment tool 200 may be opened.

The vibration member 300 may be coupled to the ball box 100 and may be configured to vibrate the ball box 100 in at least one of a horizontal direction or a vertical direction. The vibration member 300 may be fastened to a lower surface of the ball box 100. The vibration member 300 may vibrate the ball box 100 in the horizontal direction so that the solder balls SB are uniformly distributed inside the pocket portion 120. Further, the vibration member 300 may vibrate the ball box 100 in the vertical direction so that the solder balls SB accommodated in the ball box 100 bounce upward. The vibration member 300 may be constituted by a vibrator (not shown) or a linear motor (not shown), but is not limited thereto.

The solder ball attachment tool 200 may apply suction pressure through one surface thereof and may adsorb the solder balls SB accommodated in the ball box 100 using the suction pressure. The solder ball attachment tool 200 descends toward the ball box 100 so that the solder ball attachment tool 200 is located at a position close to the pocket portion 120. The solder ball attachment tool 200 adsorbs the solder balls SB bounced by the vibration applied by the vibration member 300. The solder ball attachment tool 200 may include a frame portion 210, a suction unit 220, and a driver 240.

The frame portion 210 may constitute the overall appearance of the solder ball attachment tool 200. The frame portion 210 may include a first frame portion 212 which is provided at a lower portion of the solder ball attachment tool 200, and a second frame portion 214 which is provided on the first frame portion 212 and is connected to the first frame portion 212. The first frame portion 212 may include the lower surface 200S of the solder ball attachment tool 200 in which adsorption holes 222 are formed.

The suction unit 220 may include a vacuum pump 226, and a vacuum space 224 may be provided inside the frame portion 210. The large number of adsorption holes 222 formed in the first frame portion 212 provide fluidic paths from the vacuum space 224 to the lower surface 200S of the solder ball attachment tool 200. The vacuum pump 226 may decompress the vacuum space 224, thereby allowing suction pressure to be applied to the lower surface 200S of the solder ball attachment tool 200 through the adsorption holes 222.

The driver 240 may move the solder ball attachment tool 200 in at least one of the horizontal direction or the vertical direction. The driver 240 may move the solder ball attachment tool 200 from a first position (e.g., a standby position) to a second position, which is a position spaced apart from the ball box 100 by a desired (or alternatively, predetermined) interval, an as to adsorb the solder balls SB onto the lower surface 200S.

While the solder ball attachment tool 200 is located at the second position, the solder ball attachment tool 200 may be spaced apart from the ball box 100 by the desired (or alternatively, predetermined) interval. Thus, damage of the solder ball attachment tool 200 due to contact with the ball box 100 may be prevented or mitigated. Further, the interval between the solder ball attachment tool 200 at the second position and the ball box 100 may be determined in consideration of the displacement of the ball box 100 by the vibration member 300. For example, the second position may be a position where the lower surface 200S of the solder ball attachment tool 200 is spaced from the bottom surface (122 in FIG. 2) of the pocket portion 120 at approximately 3 mm.

When the solder ball attachment tool 200 descends by the driver 240 to be located at the second position, the vibration member 300 may vibrate the ball box 100 in a vertical direction, and thus the solder balls SB accommodated in the pocket portion 120 may bounce. At this time, a vibration width of the ball box 100 by the vibration member 300 may be determined in consideration of the weight and size of the solder ball SB. The solder ball attachment tool 200 may apply suction pressure to the lower surface 200S thereof to thereby adsorb the solder balls SB bounced close to the lower surface 200S.

Subsequently, referring to FIG. 6, the solder ball attachment tool 200 adsorbs solder balls SB onto the lower surface thereof, and the solder ball attachment tool 200 may move to a position (e.g., a third position), under which a semiconductor substrate M onto which the solder balls SB are to be attached by the driver 240 is placed.

Ball landing pads (not shown) to which solder balls SB may be attached may be formed on one surface of the semiconductor substrate M, for example, in a fixed pattern, and flux may be applied onto the ball landing pad before the solder balls SB are attached.

Further, the adsorption holes 222 provided in the lower surface 200S of the solder ball attachment tool 200 may be formed to have a pattern corresponding to the ball landing pads provided on the semiconductor substrate M. Each of the adsorption holes 222 may adsorb one solder ball SB. When the solder ball attachment tool 200 descends to the semiconductor substrate M, suction pressure applied through the adsorption holes 222 may be removed, and the solder balls SB separated from the solder ball attachment tool 200 may be attached onto the ball landing pad of the semiconductor substrate M.

Referring back to FIG. 5, while the solder ball attachment tool 200 is located at the second position, the pocket portion 120 may accommodate a portion of the solder ball attachment tool 200. For example, the lower surface 200S of the solder ball attachment tool 200 may be located between the first level L1 and the second level L2. Thus, the side wall 124 in FIG. 2 of the ball box 100 may extend to a level higher than the height level of the lower surface 200S of the solder ball attachment tool 200 at the second position.

While the ball box 100 is vibrated by the vibration member 300, the solder balls SB accommodated in the pocket portion 120 may bounce upward. Further, the solder balls SB may bounce to a height higher than a height desired by the vibration member 300 due to collisions between themselves, and thus the solder balls SB may escape the pocket portion 120 or even the ball box 100.

For example, when the ball box 100 is vibrated by the vibration member 300, the solder balls SB may bounce into a space between the pocket portion 120 and the solder ball attachment tool 200. The lower surface 200S of the solder ball attachment tool 200 may be located at a position lower than the height of the side wall of the pocket portion 120 to reduce a distance for the solder balls SB to reach the lower surface 200S of the solder ball attachment tool.

Further, the pocket portion 120 may overlap the solder ball attachment tool 200 with respect to a direction perpendicular to the bottom surface 122 in FIG. 2 of the pocket portion 120. The solder balls SB located at the edge of the pocket portion 120 can escape from the pocket portion 120 while bouncing. However, because the solder ball attachment tool 200 covers an upper portion of the edge of the pocket portion 120, the solder balls SBs located at the edge of the pocket portion 120 collide with the solder ball attachment tool 200 in spite of their upward bouncing. Most of the solder balls SB having collided with the solder ball attachment tool 200 may directly move to the pocket portion 120 or may move to the pocket portion 120 by the inclined portion 130.

Referring to FIGS. 5 and 7, the first frame portion 212 and the second frame portion 214 have a first width W1 and a second width W2, respectively The second width W2 may he larger than the first width W1. Accordingly, the side surface of the solder ball attachment tool 200 may have a stair-like structure in which the height becomes smaller toward the lower surface 200S from the upper surface thereof. At this time, the first width W1 may be smaller than a width W0 of the pocket portion 120, and the second width W2 may be larger than the width W0 of the pocket portion 120.

When the solder ball attachment tool 200 is located at the second position in order to adsorb solder balls SB, a portion of the first frame portion 212 having a width smaller than the width W0 of the pocket portion 120 may be accommodated in the pocket portion 120. For example, a lower surface of the first frame portion 212 may be located at a region lower than a height level (e.g., the second level L2 in FIG. 2) of a boundary between the pocket portion 120 and the inclined portion 130. The second frame portion 214 having a width larger than that of the pocket portion 120 may be located at a position higher than the height level of the boundary between the pocket portion 120 and the inclined portion 130.

Even when solder balls SB bounced inside the pocket portion 120 escape from a gap between the first frame portion 212 and the pocket portion 120, the second frame portion 214 located above the gap may mitigate or prevent the solder balls SB having escaped from the gap from escaping to the outside of the ball box 100. Solder balls SB having collided with the second frame portion 214 may directly move toward the pocket portion 120, or may be collected in the pocket portion 120 again along the inclined surface provided by the inclined portion 130.

Referring to FIGS. 5 and 8, in order to mitigate or prevent damage that may occur when the solder ball attachment tool 200 comes into contact with the ball box 100 while the solder ball attachment tool 200 is descending to the second position, the second frame portion 214 may be spaced apart from the boundary between the pocket portion 120 and the inclined portion 130 by a desired (or alternatively, fixed distance). A distance D between a bottom surface of the second frame portion 214 and the boundary between the pocket portion 120 and the inclined portion 130 may be determined in consideration of the width of vibration of the ball box 100, and may be equal to or greater than approximately 2 mm.

Hereinafter, a description will be given of a method of arranging solder balls in a ball landing pad of a semiconductor substrate using a solder ball attachment apparatus having the above-described configuration.

Referring to FIGS. 1 and 3, the solder ball supplier 400 may supply a large number of solder balls SB to the ball box 100. The solder ball supplier 400 may drop the solder balls SB onto the inclined portion 130 of the ball box 100, and the solder balls SB may move to the pocket portion 120 while moving along or being guided by the inclined surface 130. The inclined portion 130 may include the concave surface 134. At this time, the solder balls SB may fall onto the concave surface 134, and the large number of solder balls SB moving along the concave surface 134 may be diffused into the pocket portion 120 at a relatively high speed.

Referring to FIG. 5, the solder ball attachment tool 200 descends in a direction directed to one opened surface of the ball box 100, and is located at a position spaced from the bottom surface of the pocket portion 120 by a fixed distance. The vibration member 300 vibrates the ball box 100 in a vertical direction so that solder balls SB accommodated in the pocket portion 120 bounce upward. The vacuum pump 226 decompresses the vacuum space 224 to thereby apply suction pressure through the adsorption holes 222 formed in the lower surface 200S of the solder ball attachment tool 200 and to adsorb the solder balls SB bounced to a height close to the lower surface 200S. The adsorption holes 222 are formed in the lower surface 200S of the solder ball attachment tool 200 in a fixed pattern, and one of the adsorption holes 222 may adsorb one solder ball SB.

In a process of applying vibration to the ball box 100 to bounce upward the solder balls SB accommodated in the pocket portion 120, the solder balls SB may be bounced to a height higher than a height desired by the vibration due to collisions between themselves, and thus some of the solder balls SB may escape the pocket portion 120 or even outside of the ball box 100. The pocket portion 120 accommodating the solder balls SB may overlap the solder ball attachment tool 200 which is located above the pocket portion 120, and the solder balls SB bounced to a height higher than a desired (or alternatively, fixed) height may be moved back to the pocket portion 120 by colliding with the solder ball attachment tool 200. Further, the solder balls SB having escaped from the gap between the pocket portion 120 and the solder ball attachment tool 200 may be located on the inclined portion 130, and be moved back to the pocket portion 120 while moving along or being guided by the inclined portion 130.

Referring to FIG. 6, the solder ball attachment tool 200 moves to one surface of the semiconductor substrate M with solder balls SB adsorbed onto the lower surface thereof. A ball landing pad having solder balls SB seated thereon may be formed on one surface of the semiconductor substrate M, and the ball landing pad may have a desired or fixed pattern. The ball landing pad and the adsorption holes 222 may be arranged in the same pattern. The solder ball attachment tool 200 may remove suction pressure so that the solder balls SB are released to be seated on the ball landing pad.

While the inventive concepts has been particularly shown and described with reference to some example embodiments thereof, it will be understood that various changes in form and details may be made therein without departing from the spirit and scope of the following claims.

What is claimed is:

1. A solder ball attachment apparatus comprising:
an open ball box configured to accommodate a plurality of solder balls, the open ball box including,
a pocket portion at a bottom thereof, the pocket portion configured to accommodate the solder balls, and
an inclined portion extending from the pocket portion toward an outer surface of the open ball box,
a solder ball attachment tool configured to apply suction pressure to a lower surface thereof, the lower surface configured to face the open ball box, the lower surface configured to adsorb the solder balls accommodated in the ball box by moving between a first position and a second position, the first position being a standby position, the second position being a position for adsorbing the solder balls; and
a vibration member connected to the open ball box.

2. The apparatus of claim 1, wherein the pocket portion comprises a bottom surface having a first level, and a side surface extending from an edge of the bottom surface to a second level higher than the first level.

3. The apparatus of claim 2, wherein when the solder ball attachment tool is positioned at the second position, the solder ball attachment tool is spaced apart from the bottom surface and the side surface of the pocket portion, and the lower surface is located between the first level and the second level.

4. The apparatus of claim 1, wherein the solder ball attachment tool comprises a first frame portion and a second frame portion, the first frame portion having a first width, the second frame portion above the first frame portion, the second frame portion having a second width larger than the first width.

5. The apparatus of claim 4, wherein the pocket portion has a width larger than the first width and smaller than the second width.

6. The apparatus of claim 5, wherein when the second frame portion is positioned at the second position spaced apart from a boundary between the pocket portion and the inclined portion, the apparatus is configured to have a height difference between a bottom surface of the second frame portion and the boundary of at least approximately 2 mm or more.

7. The apparatus of claim 1, wherein the inclined portion is connected to the pocket portion and surrounds the pocket portion.

8. The apparatus of claim 1, wherein the inclined portion extends from a first point to a second point, the first point connected to the pocket portion, the second point spaced apart from the first point by a distance in a direction toward the outer surface of the open ball box, a height of the second point being higher than that of the first point.

9. The apparatus of claim 9, the inclined portion comprises a concave surface.

10. The apparatus of claim 1, wherein the pocket portion constitutes a rectangular parallelepiped space.

11. A solder ball attachment ball box comprising:
an open ball box including,
a pocket portion at a bottom portion thereof, the pocket portion configured to accommodate a plurality of solder balls; and
an inclined portion extending from the pocket portion toward an outer surface of the open ball box.

12. The solder ball attachment ball box of claim 11, wherein the pocket portion is spaced apart from the outer surface of the open ball box by the inclined portion interposed therebetween.

13. The solder ball attachment ball box of claim 12, wherein the inclined portion comprises an inclined surface and a concave surface, the inclined surface connected to the pocket portion, the concave surface connected to the inclined surface.

14. The solder ball attachment ball box of claim 11, wherein the pocket portion comprises a bottom surface and a side surface, the side surface of the pocket portion extending from an edge of the bottom surface, and the bottom surface and the side surface constitute a rectangular parallelepiped space.

15. The solder ball attachment ball box of claim 11, wherein a height level of the inclined portion increases toward the outer surface of the body.

16. A solder ball attachment apparatus comprising:
a body having an opening on a top side thereof, and
an interior surface defining,
a pocket portion configured to accommodate the solder balls, the pocket portion aligned with the opening of the body, and
an inclined portion extending from the pocket portion toward an exterior side surface of the body.

17. The apparatus of claim 16, wherein the inclined portion comprises a concave surface.

18. The apparatus of claim 16, wherein the inclined portion extends from a first point to a second point, the first point connected to the pocket portion, the second point spaced apart from the first point by a distance in a direction toward the exterior side surface of the body, a height of the second point being higher than that of the first point.

19. The apparatus of claim 16, further comprising:
a solder ball attachment tool configured to apply suction pressure to a lower surface thereof, the solder ball attachment tool configured to ascend and descend, the solder ball attachment tool configured to face the body at the lower surface thereof and adsorb the solder balls accommodated in the body.

20. The apparatus of claim 19, further comprising:
a vibration member configured to vibrate the body.
